(19) United States
(12) Patent Application Publication
(10) Pub. No.: US 2025/0199086 A1
(43) Pub. Date: Jun. 19, 2025

(54) ABNORMALITY DETECTION CIRCUIT, MOTOR DRIVE DEVICE, MOTOR SYSTEM, AND VEHICLE

(71) Applicant: ROHM CO., LTD., Kyoto-shi (JP)

(72) Inventor: Takashi FUJIMURA, Kyoto-shi (JP)

(21) Appl. No.: 19/063,781

(22) Filed: Feb. 26, 2025

Related U.S. Application Data
(63) Continuation of application No. PCT/JP2023/025701, filed on Jul. 12, 2023.

(30) Foreign Application Priority Data
Sep. 7, 2022 (JP) 2022-141985

(51) Int. Cl. G01R 31/52; G01R 15/04; G01R 19/165

(52) U.S. Cl. CPC G01R 31/52; G01R 15/04; G01R 19/16504; G01R 19/16533

(57) ABSTRACT

This abnormality detection circuit is configured so as to detect abnormality of a first half bridge including a first switching element and a second switching element. The abnormality detection circuit includes: a series circuit of a first switch and a first resistor provided between a first node which is a connection node for the first switching element and the second switching element and a second node configured so as to have a first constant voltage applied thereto; and a first comparator configured so as to compare a first reference voltage and a voltage corresponding to the voltage of the first node.

### CROSS-REFERENCE TO RELATED APPLICATIONS

This application is a continuation under 35 U.S.C. § 120 of International Patent Application No. PCT/JP2023/025701 filed on Jul. 12, 2023, which is incorporated herein by reference, and which claimed priority to Japanese Patent Application No. 2022-141985 filed on Sep. 7, 2022. The present application likewise claims priority under 35 U.S.C. § 119 to Japanese Application No. 2022-141985, filed Sep. 7, 2022, the entire content of which is also incorporated herein by reference.

### BACKGROUND OF THE INVENTION

### 1. Technical Field

The invention herein disclosed relates to an abnormality detection circuit, as well as to a motor drive device, a motor system and a vehicle each equipped with the abnormality detection circuit.

### 2. Description of Related Art

Conventionally, there has been provided an abnormality detection circuit enabled to detect abnormalities on a basis of rotational state of a motor resulting under a motor-driven condition (see, e.g., JP 2015-226450 A).

### BRIEF DESCRIPTION OF DRAWINGS

FIG. 1 is a diagram showing a schematic configuration of a motor system according to a first embodiment;

FIG. 2 is a chart showing contents of abnormality detection;

FIG. 3 is a diagram showing a schematic configuration of a motor system according to a second embodiment;

FIG. 4 is a diagram showing a schematic configuration of a motor system according to a third embodiment;

FIG. 5 is a diagram showing a schematic configuration of a motor system according to a fourth embodiment;

FIG. 6 is a chart showing contents of abnormality detection;

FIG. 7 is a diagram showing a schematic configuration of a motor system according to a fifth embodiment;

FIG. 8 is a diagram showing a schematic configuration of a motor system according to a sixth embodiment; and

FIG. 9 is a view showing a state in which a motor system is mounted on a vehicle.

### DESCRIPTION OF EMBODIMENT

Herein, the term ‘MOS transistor’ refers to a field-effect transistor having a gate structure composed of at least three layers that include a “layer made from an electrical conductor or low-resistance polysilicon or other semiconductor”, an “insulating layer”, and a “P-type, N-type or intrinsic semiconductor layer”. That is, the gate structure of the MOS transistor is not limited to a metal-oxide-semiconductor tri-layer structure.

Herein, the term ‘constant voltage’ refers to a voltage which is constant under an ideal condition, and which actually can slightly fluctuate due to temperature variations or the like.

Herein, the term ‘reference voltage’ refers to a voltage which is constant under an ideal condition, and which actually can slightly fluctuate due to temperature variations or the like.

### First Embodiment

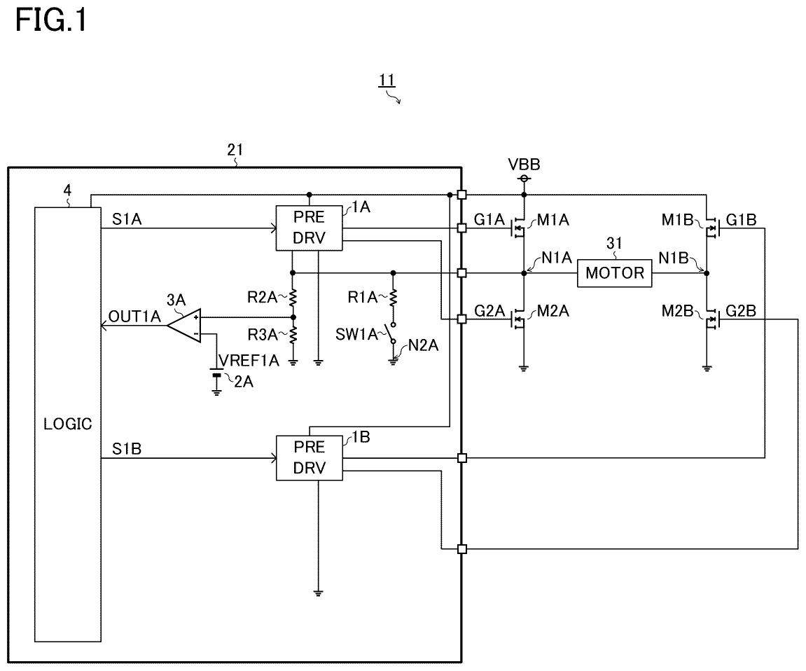

FIG. 1 is a diagram showing a schematic configuration of a motor system 11 according to a first embodiment. The motor system 11 includes a motor drive device 21, which is a so-called motor driver IC (Integrated Circuit), and switching elements M1A, M2A, M1B and M2B as well as a motor 31.

The motor drive device 21 drives the motor 31 via the switching elements M1A, M2A, M1B and M2B. In this embodiment, the switching elements M1A, M2A, M1B and M2B are externally connected to the motor drive device 21. In cases unlike this embodiment, the switching elements M1A, M2A, M1B and M2B may instead be internally provided in the motor drive device 21. Also in this embodiment, the switching elements M1A, M2A, M1B and M2B are N-channel MOS transistors. In cases unlike this embodiment, the switching elements M1A, M2A, M1B and M2B may instead be switching elements other than N-channel MOS transistors. Such switching elements other than N-channel MOS transistors may be, for example, P-channel MOS transistors, IGBTs (Insulated Gate Bipolar Transistors), transistors using SiC or other compound semiconductor, and the like.

The motor drive device 21 includes pre-drivers 1A and 1B, a reference voltage source 2A, a comparator 3A, a logic unit 4, resistors R1A, R2A and R3A, and a switch SW1A. The motor drive device 21 also includes a bootstrap circuit (not shown) for the switching elements M1A and M1B, a rotational-speed detection unit (not shown) operable to detect rotational speed of a rotor provided in the motor 31, and the like.

A power supply voltage VBB, which is a constant voltage, is applied to drains of the switching elements M1A and M1B, the pre-drivers 1A and 1B, and the logic unit 4.

The motor 31 is provided between a node NIA and a node NIB. More specifically, a stator coil (not shown) of the motor 31 is provided between the node NIA and the node NIB. The stator coil (not shown) of the motor 31 is an example of a load provided between the node NIA and the node NIB. Resistance of the stator coil (not shown) of the motor 31 is small enough as compared with resistances of the resistors R1A, R2A and R3A. The node NIA is a connection node between the source of the switching element M1A and the drain of the switching element M2A. The node NIB is a connection node between the source of the switching element M1B and the drain of the switching element M2B.

A ground voltage, which is a constant voltage lower than the power supply voltage VBB, is applied to the sources of the switching elements M1A and M1B. The ground voltage that is a constant voltage lower than the power supply voltage VBB is supplied also to the pre-drivers 1A and 1B.

The logic unit 4 performs on/off control over the switching elements M1A, M2A, M1B and M2B. The logic unit 4 supplies the pre-driver 1A with a switch signal S1A used to perform on/off control over the switching elements M1A and M2A. The logic unit 4 supplies the pre-driver 1B with a switch signal SIB used to perform on/off control over the switching elements M1B and M2B.

The pre-driver 1A generates gate signals G1A and G2A corresponding to the switch signal S1A and supplies the gate signal G1A to the gate of the switching element M1A while supplying the gate signal G2A to the gate of the switching element M2A.

The pre-driver 1B generates gate signals GIB and G2B corresponding to the switch signal SIB and supplies the gate signal G1B to the gate of the switching element M1B while supplying the gate signal G2B to the gate of the switching element M2B.

An abnormality detection circuit, which is configured from the reference voltage source 2A, the comparator 3A, the resistors R1A, R2A and R3A, the switch SW1A, and the logic unit 4, detects abnormalities of a half bridge including the switching elements M1A and M2A.

A first end of the resistor R1A and a first end of the resistor R2A are connected to the node NIA. A second end of the resistor R1A is connected to a node N2A via the switch SW1A. A ground voltage, being a constant voltage, is applied to the node N2A. That is, a series circuit of the resistor R1A and the switch SW1A is provided between the node NIA and the node N2A. While the switch SW1A keeps on, the resistor R1A serves as a pull-down resistor.

A second end of the resistor R2A is connected to a first end of the resistor R3A and a noninverting input terminal of the comparator 3A. The ground voltage is applied to a second end of the resistor R3A.

The reference voltage source 2A supplies an inverting input terminal of the comparator 3A with a reference voltage VREF1A. The comparator 3A supplies the logic unit 4 with a signal OUT1A which is a result of comparison made between a voltage corresponding to a voltage of the node NIA (a voltage obtained by dividing the voltage of the node NIA by the resistors R2A and R3A) and the reference voltage VREF1A.

A current is supplied from the pre-driver 1A to the series circuit of the resistors R2A and R3A. A value obtained by multiplying the current and a resistance of the resistor R3A together is set so as to be larger than the reference voltage VREF1A. That is, the reference voltage VREF1A is smaller than a voltage drop of the resistor R3A resulting under an off-state condition of the switch SW1A. As a result of this, the signal OUT1A goes high level under an initial-state condition, i.e., a condition that the switching elements M1A and M2A are off while the switch SW1A is off.

Also, the resistance of the resistor R3A is set so as to be larger than the resistance of the resistor R1A. As a result of this, when the switch SW1A is turned on, the voltage supplied to the noninverting input terminal of the comparator 3A goes low level with reliability.

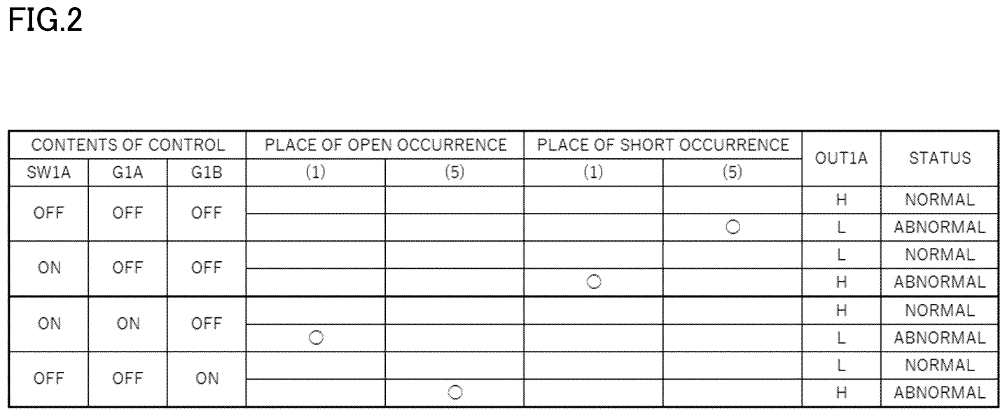

The logic unit 4 also performs on/off control over the switch SW1A. Depending on combinations of on/off statuses of the switching element M1A, the switching element M2A, the switch SW1A and, as combined therewith, levels of the signal OUT1A, the logic unit 4 detects abnormalities of the half bridge including the switching elements M1A and M2A. More concretely, the logic unit 4 detects abnormalities with contents shown in FIG. 2. Column number (1) in FIG. 2 denotes that the switching element M1A is a place of abnormality occurrence, and column number (5) in FIG. 2 denotes that the switching element M2A is a place of abnormality occurrence.

The abnormality detection circuit provided in the motor drive device 21 is enabled to detect abnormalities even with the motor 31 non-driven.

Also, the abnormality detection circuit provided in the motor drive device 21 is enabled to prevent a current from constantly flowing through the resistor R1A by the logic unit 4 keeping the switch SW1A off unless an abnormality has been detected. As a result, it becomes possible to suppress wasteful consumption of currents at the resistor R1A.

Further, the abnormality detection circuit provided in the motor drive device 21 is enabled to suppress increases in circuit area by virtue of its configuration needing no more than one comparator in correspondence to the half bridge including the switching elements M1A and M2A.

### Second Embodiment

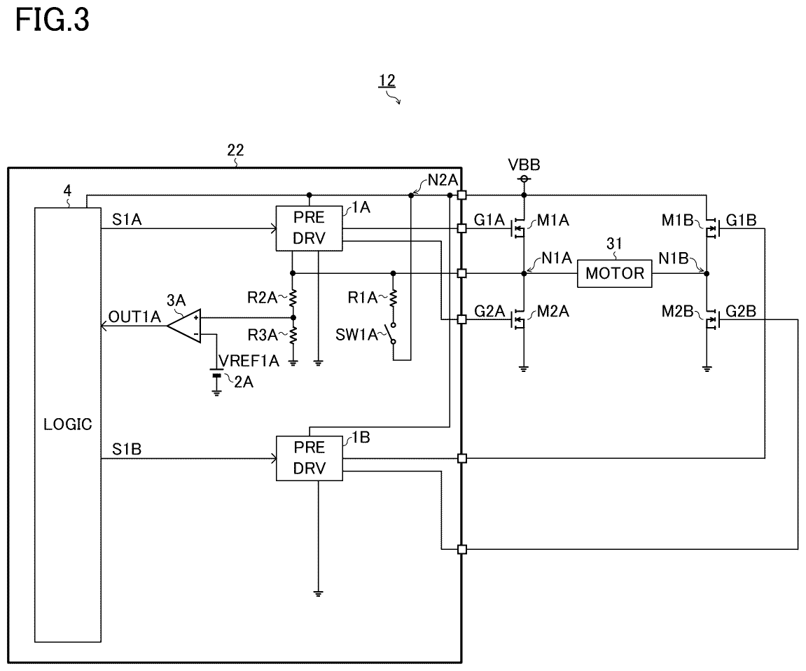

FIG. 3 is a diagram showing a schematic configuration of a motor system 12 according to a second embodiment. The motor system 12 includes a motor drive device 22, switching elements M1A, M2A, M1B and M2B, and a motor 31. It is noted that part of this embodiment similar to that of the first embodiment is omitted in description.

The motor drive device 22 differs from the motor drive device 21 in that not the ground voltage but the power supply voltage VBB is applied to the node N2A in the motor drive device 22.

In this embodiment, the reference voltage VREF1A is larger than the voltage drop of the resistor R3A resulting under an off-state condition of the switch SW1A. As a result of this, the signal OUT1A goes low level under an initial-state condition, i.e., a condition that the switching elements M1A and M2A are off while the switch SW1A is off.

Also in this embodiment, the resistor R1A serves as a pull-up resistor under an on-state condition of the switch SW1A.

The abnormality detection circuit provided in the motor drive device 22 produces effects similar to those of the abnormality detection circuit provided in the motor drive device 21.

### Third Embodiment

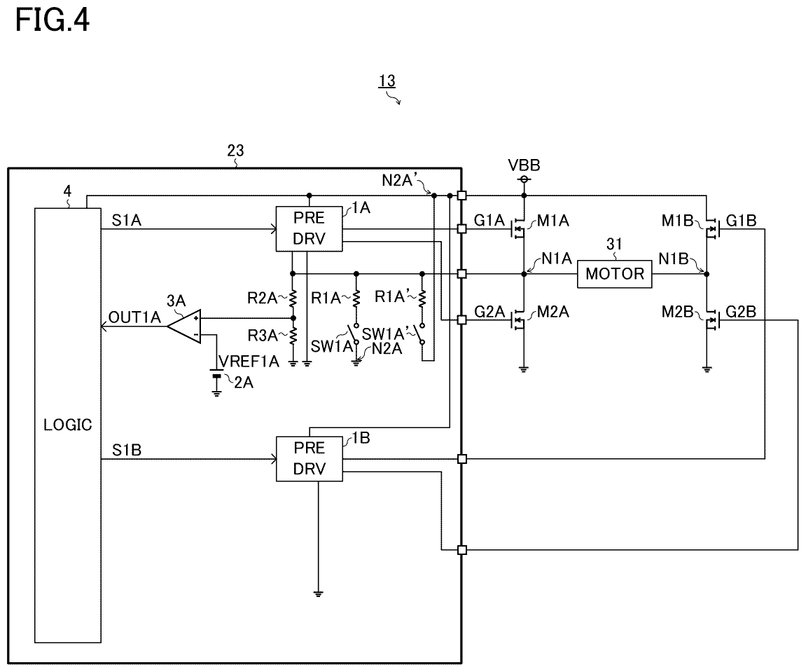

FIG. 4 is a diagram showing a schematic configuration of a motor system 13 according to a third embodiment. The motor system 13 includes a motor drive device 23, switching elements M1A, M2A, M1B and M2B, and a motor 31. It is noted that part of this embodiment similar to that of the first embodiment is omitted in description.

The motor drive device 23 differs from the motor drive device 21 in that the motor drive device 23 includes a resistor R1A′ and a switch SW1A′, and the logic unit 4 also performs on/off control over the switch SW1A′.

A first end of the resistor R1A′ is connected to the node NIA. A second end of the resistor R1A′ is connected to a node N2A′ via the switch SW1A′. That is, a series circuit of the resistor R1A′ and the switch SW1A′ is provided between the node NIA and the node N2A′. A power supply voltage VBB is applied to the node N2A′. The resistor R1A′ serves as a pull-up resistor under an on-state condition of the switch SW1A′.

In a case where abnormality detection is executed with the switch SW1A′ fixed at off, the reference voltage VREF1A is set smaller than the voltage drop of the resistor R3A under an off-state condition of the switch SW1A. Contrastively, in another case where abnormality detection is executed with the switch SW1A fixed at off, the reference voltage VREF1A is set larger than the voltage drop of the resistor R3A under an off-state condition of the switch SW1A.

The abnormality detection circuit provided in the motor drive device 23 produces effects similar to those of the abnormality detection circuits provided in the motor drive devices 21 and 22, respectively.

### Fourth Embodiment

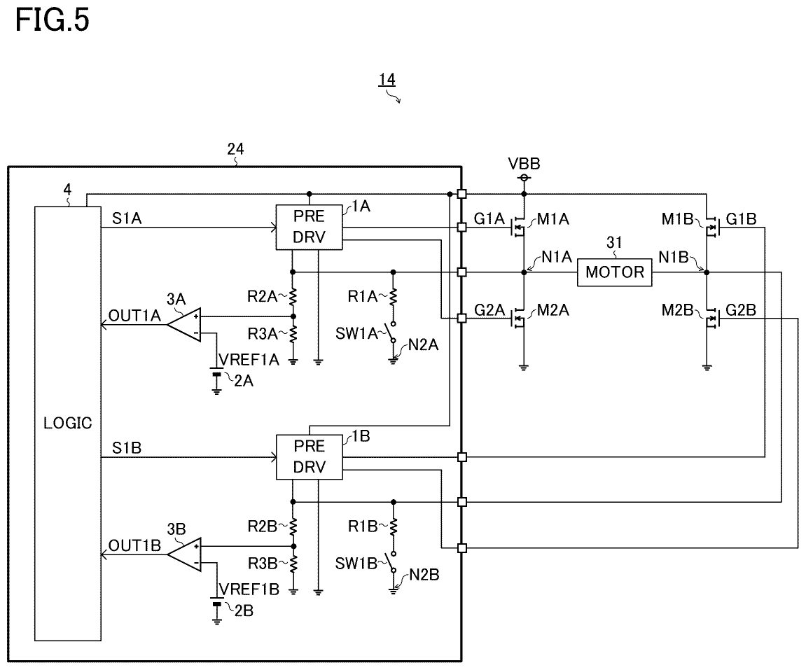

FIG. 5 is a diagram showing a schematic configuration of a motor system 14 according to a fourth embodiment. The motor system 14 includes a motor drive device 24, switching elements M1A, M2A, M1B and M2B, and a motor 31. It is noted that part of this embodiment similar to that of the first embodiment is omitted in description.

The motor drive device 24 differs from the motor drive device 21 in that the motor drive device 24 includes resistors R1B, R2B and R3B, a switch SW1B, a reference voltage source 2B, and a comparator 3B.

An abnormality detection circuit, which is configured from the reference voltage sources 2A and 2B, the comparators 3A and 3B, the logic unit 4, the resistors R1A, R2A, R3A, R1B, R2B and R3B, and the switches SW1A and SW1B, detects abnormalities of a half bridge including the switching elements M1A and M2A as well as abnormalities of a half bridge including the switching elements M1B and M2B.

A first end of the resistor R1B and a first end of the resistor R2B are connected to the node NIA. A second end of the resistor R1B is connected to a node N2B via the switch SW1B. A ground voltage, being a constant voltage, is applied to the node N2B. That is, a series circuit of the resistor R1B and the switch SW1B is provided between the node NIB and the node N2B. The resistor R1B serves as a pull-down resistor under an on-state condition of the switch SW1B.

A second end of the resistor R2B is connected to a first end of the resistor R3B and a noninverting input terminal of the comparator 3B. A ground voltage is applied to a second end of the resistor R3B.

The reference voltage source 2B supplies an inverting input terminal of the comparator 3B with a reference voltage VREF1B. The comparator 3B supplies the logic unit 4 with a signal OUT1B which is a result of comparison made between a voltage corresponding to a voltage of the node NIB (a voltage obtained by dividing the voltage of the node NIB by the resistors R2B and R3B) and the reference voltage VREF1B.

A current is supplied from the pre-driver 1B to the series circuit of the resistors R2B and R3B. A value obtained by multiplying the current and a resistance of the resistor R3B together is set so as to be larger than the reference voltage VREF1B. That is, the reference voltage VREF1B is smaller than a voltage drop of the resistor R3B resulting under an off-state condition of the switch SW1B. As a result of this, the signal OUT1B goes high level under an initial-state condition, i.e., a condition that the switching elements M1A, M2A, M1B and M2B are off while the switches SW1A and SW1B are off.

Also, the resistance of the resistor R3B is set so as to be larger than a resistance of the resistor R1B. As a result of this, when the switch SW1B is turned on, the voltage supplied to the noninverting input terminal of the comparator 3B goes low level with reliability.

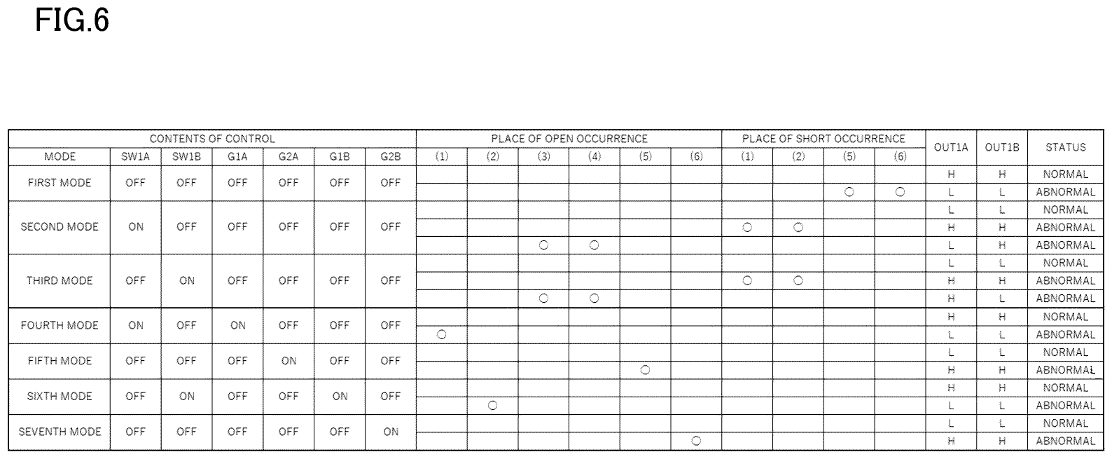

The logic unit 4 also performs on/off control over the switch SW1B. Depending on combinations of on/off statuses of the switching element M1A, the switching element M2A, the switching element M1B, the switching element M2B, the switch SW1A, the switch SW1B and, as combined therewith, levels of the signals OUT1A and OUT1B, the logic unit 4 detects abnormalities of the half bridge including the switching elements M1A and M2A as well as abnormalities of the half bridge including the switching elements M1B and M2B. More concretely, the logic unit 4 detects abnormalities with contents shown in FIG. 6.

A first mode in FIG. 6 is defined as a mode in which with the switch SW1A set off and the switch SW1B set off, the gate signal G1A is assigned as a signal (low-level signal) functioning to turn off the switching element M1A, the gate signal G2A is assigned as a signal (low-level signal) functioning to turn off the switching element M2A, the gate signal G1B is assigned as a signal (low-level signal) functioning to turn off the switching element M1B, and the gate signal G2B is assigned as a signal (low-level signal) functioning to turn off the switching element M2B.

A second mode in FIG. 6 is defined as a mode in which with the switch SW1A set on and the switch SW1B set off, the gate signal G1A is assigned as a signal (low-level signal) functioning to turn off the switching element M1A, the gate signal G2A is assigned as a signal (low-level signal) functioning to turn off the switching element M2A, the gate signal G1B is assigned as a signal (low-level signal) functioning to turn off the switching element M1B, and the gate signal G2B is assigned as a signal (low-level signal) functioning to turn off the switching element M2B.

A third mode in FIG. 6 is defined as a mode in which with the switch SW1A set off and the switch SW1B set on, the gate signal G1A is assigned as a signal (low-level signal) functioning to turn off the switching element M1A, the gate signal G2A is assigned as a signal (low-level signal) functioning to turn off the switching element M2A, the gate signal G1B is assigned as a signal (low-level signal) functioning to turn off the switching element M1B, and the gate signal G2B is assigned as a signal (low-level signal) functioning to turn off the switching element M2B.

A fourth mode in FIG. 6 is defined as a mode in which with the switch SW1A set on and the switch SW1B set off, the gate signal G1A is assigned as a signal (high-level signal) functioning to turn on the switching element M1A, the gate signal G2A is assigned as a signal (low-level signal) functioning to turn off the switching element M2A, the gate signal G1B is assigned as a signal (low-level signal) functioning to turn off the switching element M1B, and the gate signal G2B is assigned as a signal (low-level signal) functioning to turn off the switching element M2B.

A fifth mode in FIG. 6 is defined as a mode in which with the switch SW1A set off and the switch SW1B set off, the gate signal G1A is assigned as a signal (low-level signal) functioning to turn off the switching element M1A, the gate signal G2A is assigned as a signal (high-level signal) functioning to turn on the switching element M2A, the gate signal G1B is assigned as a signal (low-level signal) functioning to turn off the switching element M1B, and the gate signal G2B is assigned as a signal (low-level signal) functioning to turn off the switching element M2B.

A sixth mode in FIG. 6 is defined as a mode in which with the switch SW1A set off and the switch SW1B set on, the gate signal G1A is assigned as a signal (low-level signal) functioning to turn off the switching element M1A, the gate signal G2A is assigned as a signal (low-level signal) functioning to turn off the switching element M2A, the gate signal G1B is assigned as a signal (high-level signal) functioning to turn on the switching element M1B, and the gate signal G2B is assigned as a signal (low-level signal) functioning to turn off the switching element M2B.

A seventh mode in FIG. 6 is defined as a mode in which with the switch SW1A set off and the switch SW1B set off, the gate signal G1A is assigned as a signal (low-level signal) functioning to turn off the switching element M1A, the gate signal G2A is assigned as a signal (low-level signal) functioning to turn off the switching element M2A, the gate signal G1B is assigned as a signal (low-level signal) functioning to turn off the switching element M1B, and the gate signal G2B is assigned as a signal (high-level signal) functioning to turn on the switching element M2B.

Column number (1) in FIG. 6 denotes that the switching element M1A is a place of abnormality occurrence. Column number (2) in FIG. 6 denotes that the switching element M1B is a place of abnormality occurrence. Column number (3) in FIG. 6 denotes that a route extending from the node NIA to the motor 31 is a place of abnormality occurrence. Column number (4) in FIG. 6 denotes that a route extending from the node NIB to the motor 31 is a place of abnormality occurrence. Column number (5) in FIG. 6 denotes that the switching element M2A is a place of abnormality occurrence. Column number (6) in FIG. 6 denotes that the switching element M2B is a place of abnormality occurrence.

In the first mode, when the signals OUT1A and OUT1B are both at high level, the logic unit 4 decides that no abnormality has occurred.

In the first mode, when the signals OUT1A and OUT1B are both at low level, the logic unit 4 decides that there has occurred an abnormality, i.e., at least one of the switching elements M2A and M2B has short-circuited, causing a ground fault.

In the second mode, when the signals OUT1A and OUT1B are both at low level, the logic unit 4 decides that no abnormality has occurred.

In the second mode, when the signals OUT1A and OUT1B are both at high level, the logic unit 4 decides that there has occurred an abnormality, i.e., at least one of the switching elements M1A and M1B has short-circuited, causing a short-to-power fault. It is noted that restricting the current flowing through the motor 31 by means of the resistance of the resistor R1A allows a short-circuit of at least one of the switching elements M1A and M1B to be detected without involving rotation of the rotor of the motor 31.

In the second mode, when the signal OUT1A is at low level and the signal OUT1B is at high level, the logic unit 4 decides that there has occurred an abnormality, i.e., at least one of a route extending from the node NIA to the motor 31 and a route extending from the node NIB to the motor 31 has come to an open state.

In the third mode, when the signals OUT1A and OUT1B are both at low level, the logic unit 4 decides that no abnormality has occurred.

In the third mode, when the signals OUT1A and OUT1B are both at high level, the logic unit 4 decides that there has occurred an abnormality, i.e., at least one of the switching elements M1A and M1B has short-circuited, causing a short-to-power fault. It is noted that restricting the current flowing through the motor 31 by means of the resistance of the resistor R1A allows a short-circuit of at least one of the switching elements M1A and M1B to be detected without involving rotation of the rotor of the motor 31.

In the third mode, when the signal OUT1A is at high level and the signal OUT1B is at low level, the logic unit 4 decides that there has occurred an abnormality, i.e., at least one of a route extending from the node NIA to the motor 31 and a route extending from the node NIB to the motor 31 has come to an open state.

In the fourth mode, when the signals OUT1A and OUT1B are both at high level, the logic unit 4 decides that no abnormality has occurred. In the fourth mode, since only the switching element M1A among the four switching elements can be turned on, the rotor of the motor 31 is kept from rotating.

In the fourth mode, when the signals OUT1A and OUT1B are both at low level, the logic unit 4 decides that there has occurred an abnormality, i.e., the switching element M1A has come to an open state.

In the fifth mode, when the signals OUT1A and OUT1B are both at low level, the logic unit 4 decides that no abnormality has occurred. In the fifth mode, since only the switching element M2A among the four switching elements can be turned on, the rotor of the motor 31 is kept from rotating.

In the fifth mode, when the signals OUT1A and OUT1B are both at high level, the logic unit 4 decides that there has occurred an abnormality, i.e., the switching element M2A has come to an open state.

In the sixth mode, when the signals OUT1A and OUT1B are both at high level, the logic unit 4 decides that no abnormality has occurred. In the sixth mode, since only the switching element M1B among the four switching elements can be turned on, the rotor of the motor 31 is kept from rotating.

In the sixth mode, when the signals OUT1A and OUT1B are both at low level, the logic unit 4 decides that there has occurred an abnormality, i.e., the switching element M1B has come to an open state.

In the seventh mode, when the signals OUT1A and OUT1B are both at low level, the logic unit 4 decides that no abnormality has occurred. In the seventh mode, since only the switching element M2B among the four switching elements can be turned on, the rotor of the motor 31 is kept from rotating.

In the seventh mode, when the signals OUT1A and OUT1B are both at high level, the logic unit 4 decides that there has occurred an abnormality, i.e., the switching element M2B has come to an open state.

In a case where a route extending from the node NIA to the resistor R1A has come to an open state, in the seventh mode, even when the signal OUT1B goes low level, the signal OUT1A does not go low level. Accordingly, in the seventh mode, the logic unit 4 is enabled to also decide whether or not the route extending from the node NIA to the resistor R1A has come to an open state.

In another case where the route extending from the node NIB to the resistor R1B has come to an open state, in the seventh mode, even when the signal OUT1A goes low level, the signal OUT1B does not go low level. Accordingly, in the seventh mode, the logic unit 4 is also enabled to decide whether or not the route extending from the node NIB to the resistor R1B has come to an open state.

In still another case where a gate-signal transmission line has come to an open state, since a switching element corresponding to the gate-signal transmission line that has come to an open state is not turned on, the logic unit 4 is also enabled to decide whether or not any gate-signal transmission line has come to an open state, on a basis of monitoring changes of the signals OUT1A and OUT1B in the fourth to seventh modes.

The abnormality detection circuit provided in the motor drive device 24 is enabled to detect abnormalities even without driving the motor 31.

Also, the abnormality detection circuit provided in the motor drive device 24 is enabled to suppress current consumption by halting current supply from the pre-driver 1A to the resistors R2A and R3A and also halting current supply from the pre-driver 1B to the resistors R2B and R3B while the motor 31 is being driven.

Further, the abnormality detection circuit provided in the motor drive device 24 is enabled to suppress increases in circuit area by virtue of the circuit configuration in which only one comparator is needed for the half bridge including the switching elements M1A and M2A and only one comparator is needed for the half bridge including the switching elements M1B and M2B.

### Fifth Embodiment

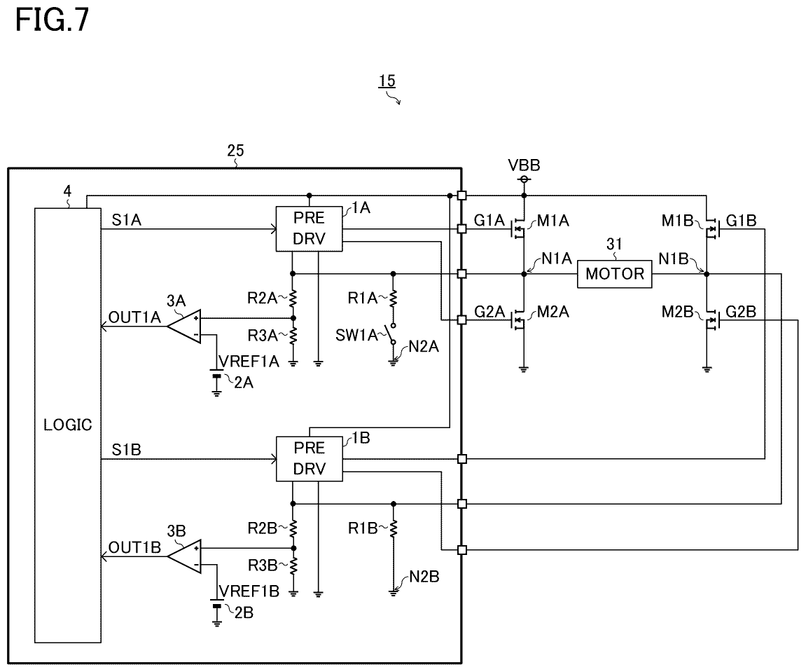

FIG. 7 is a diagram showing a schematic configuration of a motor system 15 according to a fifth embodiment. The motor system 15 includes a motor drive device 25, switching elements M1A, M2A, M1B and M2B, and a motor 31. It is noted that part of this embodiment similar to that of the fourth embodiment is omitted in description.

The motor drive device 25 differs from the motor drive device 24 in that the motor drive device 25 includes no switch SW1B.

In the fourth embodiment, abnormalities that are detectable in the second mode are detectable also in the third mode (see FIG. 6).

In this embodiment, although the second mode becomes inexecutable, abnormalities detectable in the second mode are detectable also in the third mode as described above. Accordingly, the abnormality detection circuit provided in the motor drive device 25 produces effects similar to those of the individual abnormality detection circuits provided in the motor drive device 24.

### Sixth Embodiment

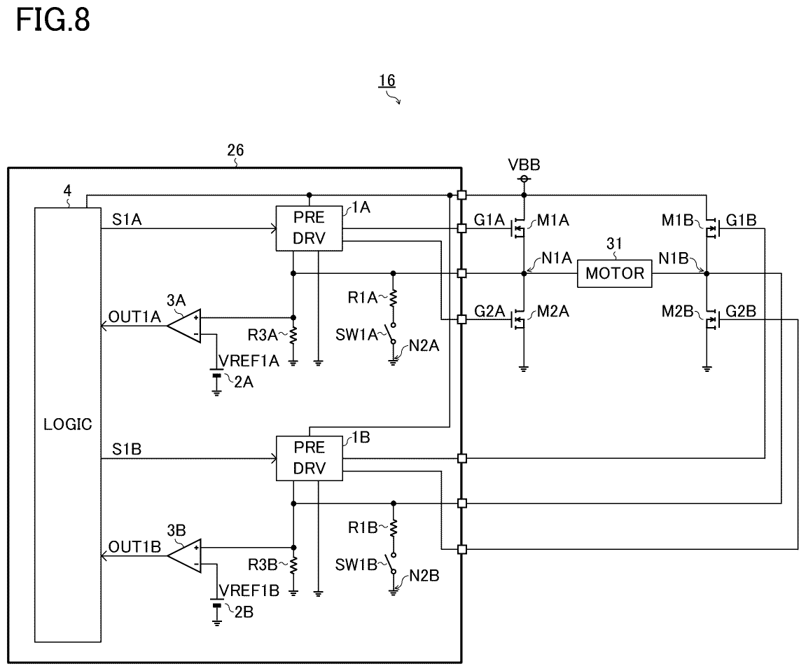

FIG. 8 is a diagram showing a schematic configuration of a motor system 16 according to a sixth embodiment. The motor system 16 includes a motor drive device 26, switching elements M1A, M2A, M1B and M2B, and a motor 31. It is noted that part of this embodiment similar to that of the fourth embodiment is omitted in description.

The motor drive device 26 differs from the motor drive device 24 in that the motor drive device 26 includes neither of the resistors R2A and R2B.

In the fourth embodiment, a voltage corresponding to the voltage of the node NIA supplied to a noninverting input terminal of the comparator 3A becomes a voltage obtained by dividing the voltage of the node NIA by the resistors R2A and R3A. A voltage corresponding to the voltage of the node NIB supplied to a noninverting input terminal of the comparator 3B becomes a voltage obtained by dividing the voltage of the node NIB by the resistors R2B and R3B.

In the fifth embodiment, contrastively, a voltage corresponding to the voltage of the node NIA supplied to the noninverting input terminal of the comparator 3A becomes the very voltage of the node NIA. A voltage corresponding to the voltage of the node NIB supplied to the noninverting input terminal of the comparator 3B becomes the very voltage of the node NIB.

Accordingly, for example, in a case where the comparators 3A and 3B do not need to be lowered in withstand voltage, it is allowable to adopt not the configuration of the fourth embodiment but the configuration of this embodiment. Adopting the configuration of this embodiment allows the abnormality detection circuit to be simplified in circuit configuration, as compared to cases in which the configuration of the fourth embodiment is adopted.

### Application Examples

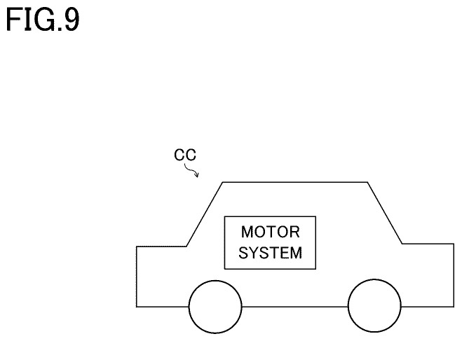

The above-described motor systems 11 to 16 are each to be mounted on a vehicle CC, such as automobiles, as exemplarily shown in FIG. 9.

The motor systems 11 to 16 to be mounted on the vehicle CC are utilized as, for example, sunroof motor systems, slide-door motor systems, EPS (Electric Power Steering) motor systems, oil-pump motor systems, and water-pump motor systems.

In addition, individual objects on which the motor systems 11 to 16 are to be mounted may be industrial equipment, consumer equipment, and the like without being limited to vehicles.

### <Others>

The embodiments disclosed herein may be modified in various ways, as appropriate, without departing from the scope of the technical concept disclosed in the appended claims. The individual embodiments described hereinabove may be carried out in combination between or among those embodiments unless any contradiction is involved. The above-described embodiments are only examples of embodiment of the present disclosure, and senses of terms in the disclosure or respective configurational components are not particularly limited to those described in the embodiments.

For example, on condition that the motor is a three- or higher-phase multiphase motor, it is allowable that a motor drive circuit drives the multiphase motor via the three or more half bridges while the abnormality detection circuit provided in the motor drive circuit includes comparators counting equal to the number of half bridges. In this case, with desired two half bridges successively selected from among the three-or-more half bridges, turning off switching elements and switches corresponding to the non-selected half bridges makes it possible to detect abnormalities in the same way as in the fourth embodiment.

### <Appendices>

Below provided are appendices relevant to the present disclosure in which specific configurational examples are given by the above-described embodiments.

The abnormality detection circuit of this disclosure is an abnormality detection circuit configured to detect abnormalities of a first half bridge including a first switching element (M1A) and a second switching element (M2A), the abnormality detection circuit comprising: a series circuit of a first switch (SW1A) and a first resistor (R1A) provided between a first node (NIA), which is a connection node for the first switching element and the second switching element, and a second node (N2A) configured so as to have a first constant voltage applied thereto; and a first comparator (3A) configured so as to compare a voltage corresponding to a voltage of the first node with a first reference voltage (first configuration).

In the abnormality detection circuit of the first configuration, the abnormality detection circuit may also be configured so as to detect not only abnormalities of the first half bridge but also abnormalities of a second half bridge including a third switching element (M1B) and a fourth switching element (M2B), the abnormality detection circuit further comprising: a second resistor (R1B) provided between a third node (N1B), which is a connection node for the third switching element and the fourth switching element, and a fourth node (N2B) configured so as to have a second constant voltage applied thereto; and a second comparator (3B) configured so as to compare a voltage corresponding to a voltage of the third node with a second reference voltage (second configuration).

In the abnormality detection circuit of the second configuration, the abnormality detection circuit may also be configured so as to further comprise a second switch (SW1B) connected in series to the second resistor (third configuration).

In the abnormality detection circuit of the second or third configuration, the abnormality detection circuit may also be so configured that a load provided between the first half bridge and the second half bridge has a resistance smaller than a resistance of the first resistor as well as than a resistance of the second resistor (fourth configuration).

In the abnormality detection circuit of any one of the first to fourth configurations, the abnormality detection circuit may further comprise a third resistor (R3A) configured so that a voltage corresponding to a voltage of the first node is applied to a first end of the third resistor while a ground voltage is applied to a second end of the third resistor, wherein the third resistor has a resistance larger than a resistance of the first resistor (fifth configuration).

In the abnormality detection circuit of the fifth configuration, the abnormality detection circuit may also be so configured that the first resistor serves as a pull-down resistor while the first switch is on, and the first reference voltage is smaller than a voltage drop of the third resistor under a condition that the first switching element and the second switching element are normal while the first switch is off (sixth configuration).

In the abnormality detection circuit of the fifth configuration, the abnormality detection circuit may also be so configured that the first resistor serves as a pull-up resistor while the first switch is on, and the first reference voltage is larger than a voltage drop of the third resistor under a condition that the first switching element and the second switching element are normal while the first switch is off (seventh configuration).

The motor drive devices (21 to 26) of this disclosure each comprise the abnormality detection circuit according to any one of the first to seventh configurations (eighth configuration).

The motor systems (11 to 26) of this disclosure each comprise: a motor (31); and the motor drive device of the eighth configuration, which is configured so as to drive the motor (ninth configuration).

The vehicle (CC) of this disclosure comprises the motor system of the ninth configuration (tenth configuration).

What is claimed is:

1. An abnormality detection circuit configured to detect abnormalities of a first half bridge including a first switching element and a second switching element, the abnormality detection circuit comprising:
a series circuit of a first switch and a first resistor provided between a first node, which is a connection node for the first switching element and the second switching element, and a second node configured so as to have a first constant voltage applied thereto; and
a first comparator configured so as to compare a voltage corresponding to a voltage of the first node with a first reference voltage.

2. The abnormality detection circuit according to claim 1 and further configured so as to detect not only abnormalities of the first half bridge but also abnormalities of a second half bridge including a third switching element and a fourth switching element, the abnormality detection circuit further comprising:
a second resistor provided between a third node, which is a connection node for the third switching element and the fourth switching element, and a fourth node configured so as to have a second constant voltage applied thereto; and
a second comparator configured so as to compare a voltage corresponding to a voltage of the third node with a second reference voltage.

3. The abnormality detection circuit according to claim 2, further comprising
a second switch connected in series to the second resistor.

4. The abnormality detection circuit according to claim 2, wherein a load provided between the first half bridge and the second half bridge has a resistance smaller than a resistance of the first resistor as well as than a resistance of the second resistor.

5. The abnormality detection circuit according to claim 1, further comprising
a third resistor configured so that a voltage corresponding to a voltage of the first node is applied to a first end of the third resistor and a ground voltage is applied to a second end of the third resistor, wherein
the third resistor has a resistance larger than a resistance of the first resistor.

6. The abnormality detection circuit according to claim 2, further comprising
a third resistor configured so that a voltage corresponding to a voltage of the first node is applied to a first end of the third resistor and a ground voltage is applied to a second end of the third resistor, wherein
the third resistor has a resistance larger than a resistance of the first resistor.

7. The abnormality detection circuit according to claim 3, further comprising
a third resistor configured so that a voltage corresponding to a voltage of the first node is applied to a first end of the third resistor and a ground voltage is applied to a second end of the third resistor, wherein
the third resistor has a resistance larger than a resistance of the first resistor.

8. The abnormality detection circuit according to claim 4, further comprising
a third resistor configured so that a voltage corresponding to a voltage of the first node is applied to a first end of the third resistor and a ground voltage is applied to a second end of the third resistor, wherein
the third resistor has a resistance larger than a resistance of the first resistor.

9. The abnormality detection circuit according to claim 5, wherein
the first resistor serves as a pull-down resistor while the first switch is on, and
the first reference voltage is smaller than a voltage drop of the third resistor under a condition that the first switching element and the second switching element are normal while the first switch is off.

10. The abnormality detection circuit according to claim 6, wherein
the first resistor serves as a pull-down resistor while the first switch is on, and
the first reference voltage is smaller than a voltage drop of the third resistor under a condition that the first switching element and the second switching element are normal while the first switch is off.

11. The abnormality detection circuit according to claim 7, wherein
the first resistor serves as a pull-down resistor while the first switch is on, and
the first reference voltage is smaller than a voltage drop of the third resistor under a condition that the first switching element and the second switching element are normal while the first switch is off.

12. The abnormality detection circuit according to claim 8, wherein
the first resistor serves as a pull-down resistor while the first switch is on, and
the first reference voltage is smaller than a voltage drop of the third resistor under a condition that the first switching element and the second switching element are normal while the first switch is off.

13. The abnormality detection circuit according to claim 5, wherein
the first resistor serves as a pull-up resistor while the first switch is on, and
the first reference voltage is larger than a voltage drop of the third resistor under a condition that the first switching element and the second switching element are normal while the first switch is off.

14. The abnormality detection circuit according to claim 6, wherein
the first resistor serves as a pull-up resistor while the first switch is on, and
the first reference voltage is larger than a voltage drop of the third resistor under a condition that the first switching element and the second switching element are normal while the first switch is off.

15. The abnormality detection circuit according to claim 7, wherein
the first resistor serves as a pull-up resistor while the first switch is on, and
the first reference voltage is larger than a voltage drop of the third resistor under a condition that the first switching element and the second switching element are normal while the first switch is off.

16. The abnormality detection circuit according to claim 8, wherein
the first resistor serves as a pull-up resistor while the first switch is on, and
the first reference voltage is larger than a voltage drop of the third resistor under a condition that the first switching element and the second switching element are normal while the first switch is off.

17. A motor drive device which comprises the abnormality detection circuit according to claim 1.

18. A motor system comprising:
a motor; and
the motor drive device according to claim 17, which is configured so as to drive the motor.

19. A vehicle which comprises the motor system according to claim 18.
